(19) United States
(12) Patent Application Publication
(10) Pub. No.: US 2002/0161961 A1
(43) Pub. Date: Oct. 31, 2002

(54) Multiple virtual machine environment management system

(75) Inventors: David S. Hardin, Cedar Rapids, IA (US); Allen P. Mass, Lisbon, IA (US); Michael H. Masters, Cedar Rapids, IA (US); Nick M. Mykris, Cedar Rapids, IA (US)

Correspondence Address: SIMMONS, PERRINE, ALBRIGHT & ELLWOOD, P.L.C., THIRD FLOOR TOWER PLACE, 22 SOUTH LINN STREET, IOWA CITY, IA, 52240, US

(73) Assignee: aJile Systems, Inc., San Jose, CA

(21) Appl. No.: 09/683,336

(22) Filed: Dec. 14, 2001

Related U.S. Application Data
(60) Provisional application No. 60/262,254, filed on Jan. 17, 2001.

(51) Int. Cl. G11C 5/00

(52) U.S. Cl. 711/6

(57) ABSTRACT

An interrupt management system for a multiple virtual machine environment is disclosed. In a system concurrently running a plurality of independent virtual machines, each virtual machine has associated therewith a plurality of anticipated interrupt signal types. A plurality of interrupt signals can be received in such a system. The interrupt signal having the highest priority is determined and that interrupt can be serviced.

### CROSS REFERENCE TO RELATED APPLICATIONS

This application claims the benefit of U.S. Provisional Application No. 60/262,254, filed on Jan. 17, 2001. The content of U.S. Provisional Application 60/262,254, filed on Jan. 17, 2001, including all text, tables, drawings and appendices, is hereby incorporated herein in its entirety by this reference.

### BACKGROUND OF THE INVENTION

Computing systems today use virtual machine architecture in many different types of applications. The use of virtual machines permit code to be written for a wide variety of computing platforms. Code can then be written independently of host hardware or operating system considerations. Systems using virtual machines also reap security and efficiency benefits. One common programming language employing virtual machines is the JAVA language. (JAVA is a trademark of Sun Microsystems, Inc.)

There exists a need, however, for a real time processor system capable of concurrently running multiple virtual machines. There exists a need in certain applications for a real time processor system that is contained on a single chip and that is capable of concurrently running multiple virtual machines. There exists a need for a multiple virtual machine management system and an interrupt system for a processor system. There is further a need for such systems that can run multiple concurrent JAVA virtual machines and that can directly execute JAVA virtual machine (JVM) bytecodes, real-time JAVA threading primitives and extended bytecodes for embedded operations. These needs, and other significant needs as well, are addressed and fulfilled by the detailed description provided below.

### BRIEF DESCRIPTION OF THE DRAWINGS

The invention may be more fully understood by reading the following description of the invention, in conjunction with the appended drawings wherein

FIG. 1 depicts a multiple virtual machine management system.

FIG. 2 depicts an embodiment of a multiple virtual machine management system within a system having a peripheral bus and a variety of peripheral devices.

FIG. 3 depicts the outputs of an external bus interface.

FIG. 4 depicts an external bus interface coupled with four memory devices.

FIG. 5 depicts a system running two concurrent virtual machines.

FIG. 6 depicts a table representing a memory protection scheme for use in a multiple virtual machine environment.

FIG. 7 depicts a chip select-based memory protection system for a multiple virtual machine environment.

FIG. 8 depicts a finer, address-based memory protection system for a multiple virtual machine environment.

FIG. 9 depicts features and functioning related to the interrupt controller component.

FIG. 10 depicts a timeline illustrating a use of the resume and abort timers to accomplish time invariant virtual machine switching.

### DETAILED DESCRIPTION

Several applications exist wherein it is desirable to concurrently run multiple virtual machines on a single processor. Some of these applications involve real-time embedded processor systems. Other important applications involve customization of some or all of the multiple virtual machines in order to better serve the resources assigned thereto. Yet other applications have a need for complete isolation between resources using different virtual machines. Still other applications require two or more of the above-described benefits. Further, multiple virtual machine systems can have the added advantage of being efficiently ported to a multi-processor system from a single, shared processor system.

A multiple virtual machine system, including related applications, advantages and embodiments, is described in detail in U.S. patent application Ser. No. 09/056,126, filed Apr. 6, 1998, entitled “Real Time Processor Capable of Concurrently Running Multiple independent JAVA Machines,” to Gee et al. U.S. patent application Ser. No. 09/056,126, filed Apr. 6, 1998, is hereby incorporated herein in its entirety, including all drawings and any appendices, by this reference. In addition, one type of virtual machine, the JAVA Virtual Machine, is described in detail in “The Java Virtual Machine Specification,” Tim Lindholm and Frank Yellin, Addison-Wesley, Inc., (2nd ed., 1999). “The Java Virtual Machine Specification,” Tim Lindholm and Frank Yellin, Addison-Wesley, Inc., (2nd ed., 1999) (ISBN 0-201 -43294-3), is hereby incorporated herein in its entirety by this reference.

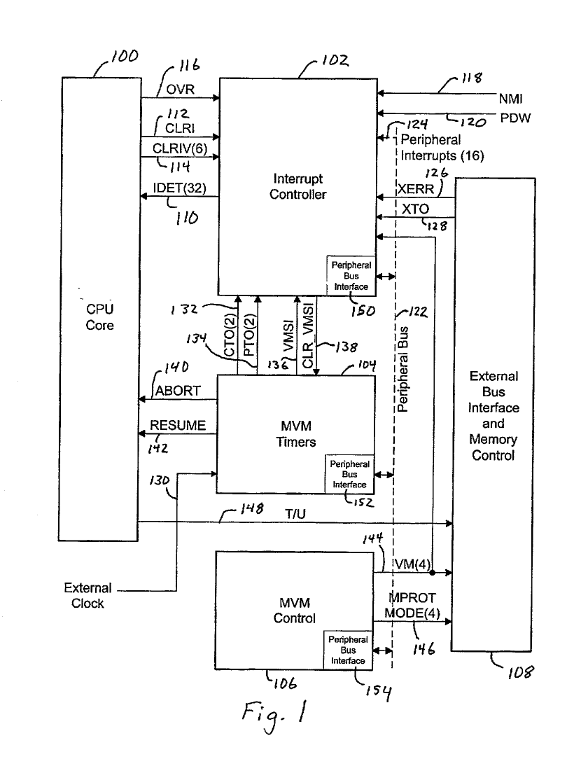

FIG. 1 depicts a system capable of concurrently running multiple independent virtual machines. If desired, the system can be contained in a single chip. The system of FIG. 1 includes a central processor unit core (CPU Core) component 100, an interrupt controller 102, a multiple virtual machine timer component 104 and a multiple virtual machine control component 106. In addition, the system can include an external bus interface and memory control component 108. In one embodiment, the system can be a JAVA-based system running multiple JAVA virtual machines. In such a case, the CPU Core 100 can be a processor executing JAVA virtual machine (JVM) bytecodes and the timer 104 and control component 106 can be tailored to the multiple JVM environment.

As noted at the conclusion of this detailed description, the invention is suitable for use with a wide variety of virtual machines. The virtual machines can be JAVA virtual machines or they can be virtual machines based on other languages. Since JVMs are currently in widespread use, some of the embodiments will be described in terms of JAVA-based systems. This is not intended, however, to limit the scope of the invention.

In one embodiment of the present invention, the CPU Core 100 can be a JAVA-based microprocessor. For example, a JAVA embedded microprocessor such as that disclosed in U.S. Pat. No. 6,317,872 B1, issued Nov. 13, 2001, can be used with the present invention. This is a real time processor that is optimized for executing JAVA programs.

The interrupt controller 102 can be coupled directly with the CPU Core 100. The interrupt controller 102 outputs an interrupt detect (IDET) signal 110 to the CPU Core 100. In one embodiment, the IDET signal is a 32 line connection. It will be appreciated, however, that the size or physical characteristics of the IDET connection, or of any of the other connections noted throughout this specification, is largely a matter of design choice and is not intended to limit the scope of the invention.

Inputs received by the interrupt controller 102 from the CPU Core 100 can include the following. The CPU Core 100 can generate a clear interrupt (CLRI) signal 112 and a clear interrupt vector (CLRIV) signal 114 when appropriate. The clear interrupt signal 112 informs the interrupt controller 102 that the given interrupt vector 114 has been latched by the CPU Core 100 and that the interrupt controller 102 can clear that interrupt from its interrupt register (for example, the virtual interrupt latch registers 922, 924, 926). In addition, the CPU Core 100 can output an arithmetic overflow (OVR) signal 116. A received OVR signal 116 may optionally generate an interrupt. Thus, if desired, additional processing can be performed even when an arithmetic overflow has occurred.

The interrupt controller 102 also receives input signals from other sources. It also receives, for example, non-maskable interrupts (NMI) 118 and power down warning (PDW) signals 120. It receives, via the peripheral bus 122, interrupts 124 generated by peripheral devices. It can also receive inputs from the external bus interface 108. For example, it can receive a memory transfer error (XERR) signal 126 and a transfer time out signal (XTO) from the EBI 108. Other signals related to the EBI 108 are discussed below.

The CPU Core 100 identifies whether the trusted or untrusted mode is active via outputting a trusted/untrusted signal (T/U) 148 to the EBI 108. The trusted and untrusted modes are disclosed in further detail in incorporated patent application Ser. No. 09/056,126, filed on Apr. 6, 1998. In addition, a multiple virtual machine system, including related applications, advantages and embodiments, is described in detail in U.S. patent application Ser. No. 09/681,136, filed Jan. 20, 2001, entitled “Improved System and Method for Concurrently Supporting Multiple Independent Virtual Machines,” to David S. Hardin et al. Application Ser. No. 09/681,136 also includes additional detail on the trusted and untrusted modes. U.S. patent application Ser. No. 09/681,136, filed Jan. 20, 2001, is hereby incorporated herein in its entirety, including all drawings and any appendices, by this reference.

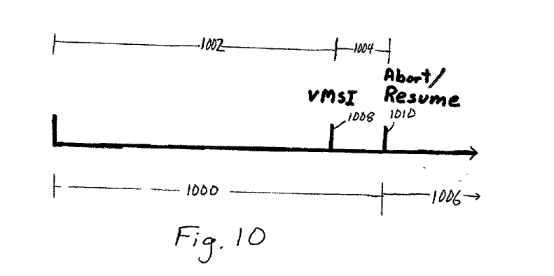

The timer component 104 receives an input signal 130 from an external clock source. The timer component 104 is also coupled with the interrupt controller 102. For example, it outputs a clock timer (CTO) 132 and a piano roll timer (PTO) 134 signal to the interrupt controller 102. It also outputs a virtual machine switch interrupt (VMSI) signal 136 to indicate the end of a virtual machine's active period. The timer component 104 also receives a clear virtual machine switch interrupt (CLR_VMSI) signal from the interrupt controller 102. In addition, the timer component 104 sends abort (ABORT) 140 and resume (RESUME) 1 42 signals to the CPU Core 100. The RESUME 142 and ABORT 140 signals are discussed further in relation to FIG. 10 below.

The multiple virtual machine control component 106 identifies the currently active virtual machine by outputting the virtual machine (VM) signal 144 to the interrupt controller 102 and the EBI 108. The multiple virtual machine control component 106 also outputs a memory protection mode (MPROTMODE) signal 146 to the EBI 108.

Each of the interrupt controller 102, the timer component 104 and the multiple virtual machine control component 106 can include a peripheral bus interface (150, 152 and 154 respectively) coupled with a peripheral bus 122. Thus, they can directly communicate with any components coupled with the peripheral bus 122. It will be appreciated that the peripheral bus 122 is not a required feature of the invention, but it can be included when dictated by design considerations.

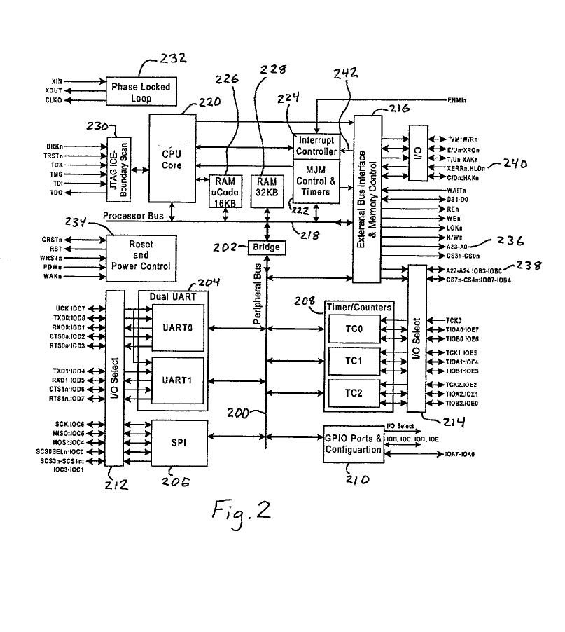

FIG. 2 depicts an embodiment of a multiple virtual machine management system within a system having a peripheral bus and a variety of peripheral devices. In particular, this environment includes a peripheral bus 200 and peripheral bus bridge 202. Several peripheral devices are couple directly or indirectly with the peripheral bus 200. The peripheral devices in this environment include a dual Universal Asynchronous Receiver/Transmitter (UART) 204, a Serial Peripheral Interface (SPI) 206, a General Purpose Timer Counter component 208, and a General Purpose Input/Output (GPIO) component 210. A first Input/Output Select and Control component 212 is coupled with the dual UART 204 and the SPI 206. A second Input/Output Select and Control component 214 is coupled with the Timer/Counter component 208 and with the External Bus Interface and Memory Control (EBI) component 216.

FIG. 2 also depicts a processor bus 218 and the components of the multiple VM management system of FIG. 1. Included are a CPU Core component 220, the MVM Control and Timer components 222, the Interrupt Controller component 224 and the EBI component 216. A test interface, which can be a standard IEEE 1149.1 (JTAG) port 230, is coupled with the CPU Core 220 to facilitate communication with software development environments. Two memory components 226, 228 are also coupled with the processor bus 218. A Phase Locked Loop (PLL) component 232 and a Reset and Power Control component 234 are also included in the environment. Additional detailed description of the components of FIG. 2 can be found in incorporated Provisional Application No. 60/262,254. It will be appreciated as well, that many additions, modifications and omissions can be made to the environment of FIG. 2. In addition, if desired, all of the components of FIG. 2 (or subsets thereof) can be housed on a single chip.

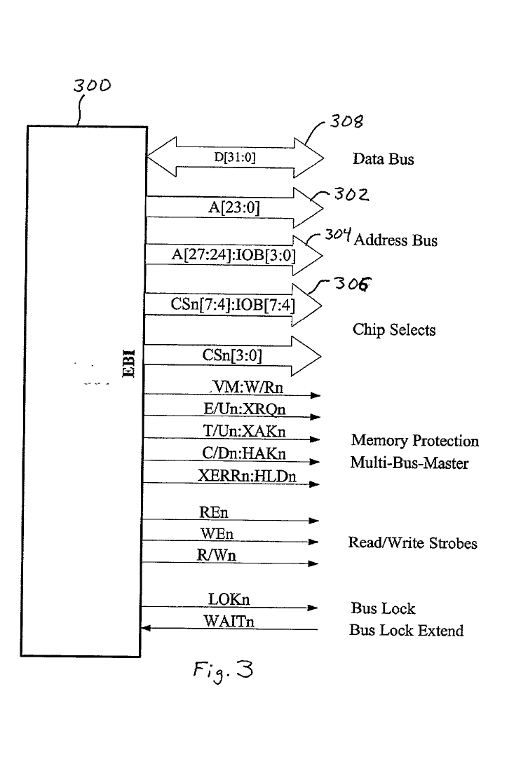

The external bus interface 108, 300 is depicted in greater detail in FIG. 3. The EBI generates signals to control access to external memory and peripheral devices. In one embodiment, the first 24 address lines 302 can access up to 16 Mbytes and with additional address lines 304 (which are accessible to further extend the memory space) a total of up to 256 MBytes can be directly accessed. In the depicted embodiment, the EBI provides access to eight chip selects 306 and it may be configured to support 32-bit, 16-bit and 8-bit memory devices. Different numbers of chip selects and differently sized memory devices can be used with the invention as needed to meet the design requirements of the application at hand. Memory control signals are provided to enable direct connection to external memory and memory-mapped input/output devices. Transactions are controlled with the internal wait state generator with an external wait signal provided to extend access to slow devices.

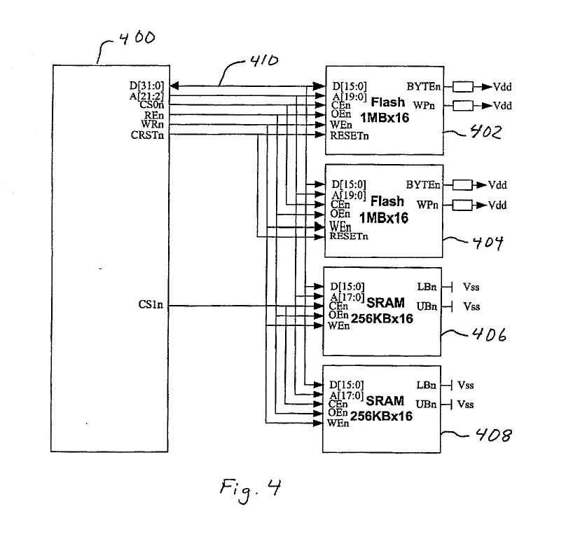

The system can be designed to interface to a variety of embedded controller applications with minimal external logic. The memory interface directly supports ROM and RAM devices. In one embodiment, the memory subsystem may be configured as 8 bits, 16 bits or 32 bits wide. Mixing of memory widths can also be supported . For example, one system can include a 32 bit ROM, a 16 bit RAM and an 8 bit EEPROM. FIG. 4 illustrates a system interfacing via the EBI 400 with Flash 402, 404 and SRAM 406, 408 memories. It will be appreciated that a variety of memory types, sizes and combinations can be included so as to meet the needs of the anticipated applications.

In one embodiment, the data bus coupled with the EBI is 32 bits wide (see for example 308, FIG. 3; or 410, FIG. 4). It can additionally or alternatively, however, support 8-bit and 16-bit memory transfers. When no memory transaction is in progress, the data bus can be tri-stated. Again, the width of the data bus can be selected so as to meet the anticipated needs of the application at hand.

In one embodiment of the invention, the address bus is always driven. In one embodiment, only the least significant twenty-eight address lines of an internal 32-bit address bus are brought out to external pins (see for example 236, 238 of FIG. 2; 302, 304 of FIG. 3). Of those lines, the most significant four bits (A[27:24]) are multiplexed with General Purpose Input/Output (GPIO) bits IOB[3:0]. These features are not a required part of the invention, however, and they can be included or excluded as circumstances warrant.

The system can be configured to run in a multi-virtual machine (multi-VM). In multi-VM mode, the system runs a plurality of virtual machines simultaneously with full space and time protection. A system running two or more applications can be simultaneously hosted on such a system with a hardware guarantee that one application cannot interfere with the other application's memory space or temporal behavior (no denial of service attack, for example, would be possible).

The multiple virtual machine feature of the system permits a plurality of independent applications to execute with a deterministic, time-sliced schedule and with full memory protection. Within its bounded execution interval and memory space, each virtual machine environment can employ its own multi-threading and memory utilization policies without threat of intervention by faulty or malicious applications.

The Multiple VM Management system (MVM) provides timing resources 104, FIG. 1, and interrupt logic 102, FIG. 1 to ensure that no virtual machine (applications) may interfere with the processing needs of the other virtual machines. As depicted in FIG. 1, the MVM provides a timer to maintain the time slices allotted to each logical virtual machine. Further, separate clock and piano timers can be provided for each virtual machine to maintain separate delay queues and schedule periodic threads.

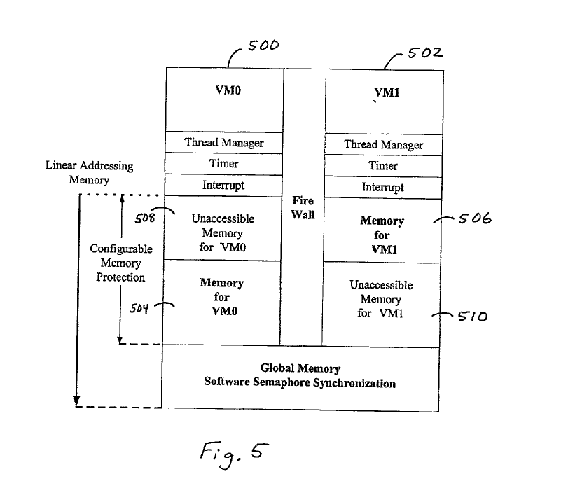

FIG. 5 depicts a system running two concurrent virtual machines (VM0 500, VM1 502). It will be appreciated that the system can be similarly constructed to run three, four or more concurrent virtual machines. If four lines 144 are used, as indicated in FIG. 1, up to sixteen different virtual machines can be identified. In operation, the system outputs (see 144, FIG. 1) the virtual machine number (VM1 500, FIG. 5, VM0 502 for example) and trusted/untrusted operating mode (T/U) indication signal 148, FIG. 1, to allow external logic to define the memory regions accessible 504, 506 for each virtual machine 500, 502 as illustrated in FIG. 5. Utilizing the address lines and these output signals, an externally located memory protection component can screen memory accesses and act to abort access to protected memory segments by generating an appropriate interrupt signal (for example the transfer error signal XERRn 126, FIG. 1; 240, 242, FIG. 2). If desired, the configuration of the memory protection system can be defined by the system designer.

Memory protection for the multiple virtual machine environment can be implemented by deciding whether an untrusted mode address being used for the current bus cycle is legal for the currently active virtual machine. The identity of the virtual machine number (which can be designated as virtual machine “0” or “1”, for example, in a system running two virtual machines) is determined from the virtual machine signal output 144, FIG. 1. Output signal “T/U” 148, FIG. 1, is used to differentiate between trusted and untrusted mode execution.

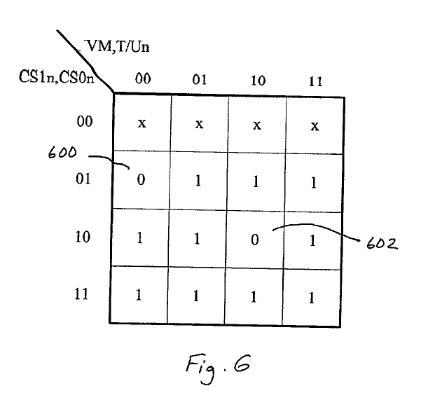

If desired, a high level of trust can be placed in the system's microcode. The microcode can be stored in, for example, an onboard RAM or ROM memory component (such as 226 or 228, FIG. 2). Whatever the processor is doing can be considered to be “trusted” such that no memory protection is necessary. In such an embodiment, the T/U signal 148, FIG. 1,can indicate “trusted” mode operation whenever the system's executive microcode is executing. (For example, the T/U signal 148 can be asserted “high” to indicate trusted mode operation.) In the table of FIG. 6, the notation T/U=1 is used to indicate trusted mode operation. Application software, on the other hand, can be considered to execute exclusively in “untrusted” mode (T/U=0 in FIG. 6). Bus transfer legality is based on the current address or chip select (CS), the virtual machine number and the T/U signal.

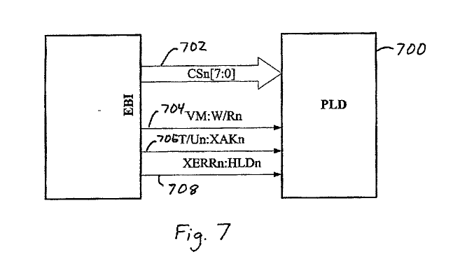

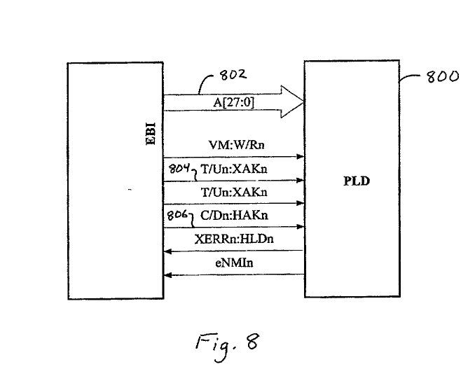

As shown in FIGS. 7 and 8, various levels of memory protection “granularity” are possible. FIGS. 7 and 8 illustrate this by presenting a “minimal” (FIG. 7) and a “full” (FIG. 8) memory protection scheme. To implement the minimal configuration depicted in FIG. 7, a Programmable Logic Device (PLD) 700 can be used to compare one or more chip selects 702 against the virtual machine number 704 and T/U signal line 706. If the PLD 700 determines that the requested transfer is illegal, it asserts an interrupt (by driving the XERRn line low for example) 708 causing the system to abort the transfer without asserting any bus command strobes.

An efficient memory protection scheme is illustrated via the truth table of FIG. 6. In this scheme, VM0 has been assigned to CS0 and VM1 has been assigned to CS1. If VM0 500 attempts to access an address in CS1's memory space 508, or if VM1 502 attempts to access an address in CS0's memory space 510, an interrupt (for example XERRn 240, 242, FIG. 2; or 708, FIG. 7) is asserted. Assertion of this interrupt is indicated by the presence of a “0” (600, 602) in the table of FIG. 6.

For the “full” memory protection configuration depicted via FIG. 8, a more complex PLD 800 can be used to fully decode the address bus 802, thus enabling much finer illegal address detection. The T/U 804 and C/Dn 806 signals can also be queried, allowing, for example, a particular virtual machine to access data in a given memory region only when executing in executive mode.

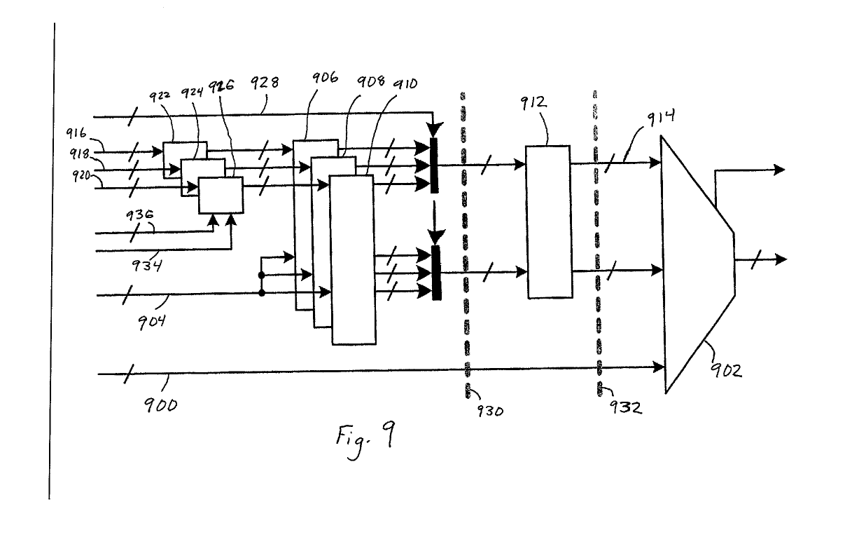

FIG. 9 depicts an architecture suitable for the interrupt controller component 102, FIG. 1; 224, FIG. 2, of the multiple virtual machine management system. Nonmaskable interrupts (NMIs) 900 are passed to the priority encoder component 902 without passing through any of the interrupt screening masks. NMls can include, for example, the virtual machine switch interrupt signal, the transfer time out interrupt or the memory access interrupt (XERR). Other potential NMIs are identified below. Other interrupts are maskable and can be characterized as temporal or virtual interrupts.

Temporal interrupts 904 are those interrupts that are only detected (passed on) when their associated virtual machine is activated at the time of their receipt. The interrupts to be treated as temporal can be defined by the system designer to meet the needs of the particular application at hand. The temporal interrupts 904 are passed to the global interrupt mask register. There is a global interrupt mask register for each virtual machine of the system. For example, a system running three virtual machines, as depicted in FIG. 9, would have three global interrupt mask registers 906, 908, 910. The global interrupt mask register defines those interrupts that are active for its associated virtual machine.

The local mask register 912 enables masking of interrupts at the application level (as opposed to the individual virtual machine level). The local mask register 912 can be a register physically distinct from the global interrupt mask register 906, 908, 910. In a different embodiment, the same register can be used for both masks and the results can be ANDed together before being sent 914 to the priority encoder component 902.

Virtual interrupts 916, 918, 920 are those interrupts that are latched whether or not their associated virtual machine is currently the activated virtual machine. In one embodiment, the Timer/Counter output (TCO) interrupt and the Piano Roll Timer Output (PTO) are designated as virtual interrupts. Other embodiments can designate only one of the TCO or PTO to be a virtual interrupt. Other types of interrupts can also be designated as virtual interrupts to meet the needs of the application at hand.

There is a virtual interrupt latch component 922, 924, 926 associated with each virtual machine. When the virtual machine associated with a particular virtual interrupt latch component 922, 924, 926 is activated, the interrupt or interrupts latched for that virtual machine are passed to its associated global interrupt mask register 906, 908 or 910 and then to the local mask register 912 and the priority encoder 902. The clear interrupt (CLRI) 112, FIG. 1; 934, FIG. 9, and the clear interrupt vector (CLRIV) 114, FIG. 1; 936, FIG. 9, discussed above, are fed to each of the virtual interrupt latch components 922, 924, 926. The virtual machine signal 144, FIG. 1; 928, FIG. 9, is used to activate the global interrupt mask register 906, 908, 910 and virtual interrupt latch component 922, 924, 926 associated with the currently activated virtual machine.

In one embodiment, the virtual interrupt latch components 922, 924, 926 and the global interrupt mask registers 906, 908, 910 are part of the interrupt controller component 102, FIG. 1. In this embodiment, the lines passing dashed line 930 correspond to the IDET signal 110 of FIG. 1. The local mask register 912 is part of the CPU Core 100 in this embodiment. In another embodiment, only the priority encoder 902 is in the CPU Core 100 and the remainder of the components of FIG. 9 (those to the left of dashed line 932) are part of the interrupt controller component 102. In yet another embodiment, all of the components of FIG. 9 are contained in the interrupt controller component 102, FIG. 1.

FIG. 10 depicts a use of the RESUME and ABORT timers noted above in relation to FIG. 1. The VM switch interrupt can be a non-maskable interrupt to signal the end of a virtual machine's active period. (Note that if the current VM is locked in an unterminated microcode execution loop, this interrupt will be ignored.) To ensure the next VM is activated, a watchdog timer (ABORT timer) is started when the VM switch interrupt is signaled. If the VM switch interrupt is not acknowledged before the ABORT timer expires, the ABORT signal is asserted to force the processor into a known state to activate the next VM context.

The ABORT timer can also be used to setup time invariant VM switching. VM switch timing is not exact since the response to the VM switch interrupt is variable depending on the execution time of the instruction interrupted. (Many instructions are multiple cycle and interrupts are typically only acknowledged between instruction execution.)

In order to make VM switching time accurate within the CPU clock cycle the following mechanism is used. FIG. 10 shows the VM activation period 1000 measured by the duration of the VM switch timer 1002 and the ABORT timer 1004. Rather than switching immediately to the next VM context 1006 upon acknowledging the VM switch interrupt 1008, the ABORT timer is used to generate a RESUME signal 1010 at the end of the ABORT timeout period. The next VM context 1006 is activated on the CPU clock cycle following the assertion of the RESUME signal 1010. Note that the acknowledge of the VM switch interrupt will also disable the ABORT signal, but the ABORT timer keeps running and the RESUME signal will be asserted at the end of the ABORT timeout period.

The following paragraphs of this specification describe various registers and their operation in relation to a system running two concurrent virtual machines. As noted above, the virtual machines may be, but are not required to be, JAVA virtual machines. The following description presents an example of a multiple virtual machine system, but it will be appreciated that the detail presented below can be modified to suit the needs of the particular project at hand. It will also be appreciated that the following description can be readily modified to support a system concurrently running three, four or more virtual machines.

MVM registers for an embodiment of a two virtual machine environment are summarized below in the MVM Register Summary table. The configuration of the MVM can be performed using an application build tool. The JEM Builder tool offered by aJile Systems, Inc., is an example of a configuration tool that can be used to automatically generate the MVM initialization data used by the system during the reset initialization sequence.

MVM Register Summary

| Address | Bits | Acronym | Description | Notes |
|---|---|---|---|---|
| FFFF_0000 | 4 | VM | VM Register | |
| FFFF_0004 | 4 | MP_MODE | Memory Protection Mode | |
| FFFF_0108 | 16 | ABO | Abort timer | read |
| | | | | only |
| FFFF_010C | 16 | ABO_RLR | Abort timer reload | |
| FFFF_0110 | 16 | PSCL_RLR | Prescalar reload | |
| FFFF_0114 | 16 | JSI_ALARM | Switch interrupt alarm | |
| | | | timer reload | |
| FFFF_0118 | 3 | TMODE | Timer mode | |
| FFFF_011C | 16 | VMSI | Switch Interrupt Timer | read |
| | | | | only |

The following two tables indicate an extended register scheme for a system running two concurrent virtual machines, each using a piano roll and each having separate piano roll and virtual machine clock timers. It will be appreciated that, in similar fashion, a system running three, four or more virtual machines can be created.

VM0 Piano Roll and Clock Timer Registers

| Address | Bits | Acronym | Description | Notes |
|---|---|---|---|---|
| FFFF_0140 | 16 | PRT_RL0 | Piano roll timer 0 reload | |
| FFFF_0144 | 16 | CT_RL0 | Clock timer 0 reload | |
| FFFF_0148 | 2 | TMR_EN0 | VMO piano roll and clock | |
| | | | timer enable | |
| FFFF_014C | 16 | PRT0 | Piano roll timer 0 | read |
| | | | | only |
| FFFF_0150 | 16 | CT0 | Clock timer 0 | read |
| | | | | only |

VM1 Piano Roll and Clock Timer Registers

| Address | Bits | Acronym | Description | Notes |
|---|---|---|---|---|
| FFFF_0160 | 16 | PRT_RL1 | Piano roll timer 1 reload | |
| FFFF_0164 | 16 | CT_RL1 | Clock timer 1 reload | |
| FFFF_0168 | 2 | TMR_EN1 | VM1 piano roll and clock | |
| | | | timer enable | |
| FFFF_016C | 16 | PRT1 | Piano roll timer 1 | read |
| | | | | only |
| FFFF_0170 | 16 | CT1 | Clock timer 1 | read |
| | | | | only |

The MVM VM register is used exclusively by the system microcode to activate a specific VM context. The first VM (typically VM0) is activated immediately after a successful reset initialization by the microcode. In response to the VM switch interrupt signal, the microcode will set the next VM number as part of the context switch to the next VM. Virtual machine context switches can be performed entirely in microcode and can therefore be transparent to the application software. The assignment of VM numbers can be configured by an appropriate builder tool such as the JEM Builder configuration tool.

MVM VM Register (VM)

| Bit Positions | 31:4 | 3:0 |
|---|---|---|
| Field Name | unused | VM Number |

Note: Accesses to the MVM VM register can be performed by microcode in trusted mode. Memory protection logic, if implemented, should only allow access to this register when trusted mode is active (for example, when T/U is asserted so as to indicate trusted mode operation).

The MVM memory protection mode register configures the system to utilize externally located memory protection logic. When memory protection is enabled, the system will not initiate a memory transfer until it checks the transfer error input signal (XERRn). The decode time-out specifies the delay time to check the XERRn signal.

If memory protection is enabled and the XERRn signal is activated (by asserting it low for example), the current memory access cycle is aborted. The XERRn signal is propagated to the XERR interrupt to allow system microcode to properly terminate execution of the active virtual machine.

MVM Memory Protection Mode (MP_MODE)

| Bit | | | | |
|---|---|---|---|---|
| Positions | 31:4 | 3:2 | 1 | 0 |
| Field | unused | Decode time- | reserved | Memory Protection |
| Names | | out | | enable |

(Decode time-out: 00 = 1T (“T” = clock tick), 01 = 2T, 10 = 3T, 11 = 4T. Memory protection enable: 0 = Memory protection disabled, 1 = Memory protection enabled.) Note: Accesses to the MVM memory protection mode register are performed by microcode in trusted mode. Memory protection logic, if implemented, should only allow access to this register when trusted mode is active (for example, when T/U is asserted so as to indicate trusted mode operation).

A read-only abort timer an be included as a watch dog timer to ensure that the virtual machine switch interrupt signal (VMSI) is acknowledged within an abort time interval. The abort timer is activated when the switch interrupt signal is generated. If the virtual machine switch interrupt signal is not acknowledged during the abort time interval, an internal abort signal is generated to force the system to terminate and disable the current virtual machine execution and force a context switch to a different virtual machine. The abort timer can be a count-down timer in units of CPU clock ticks.

Abort Timer Register (ABO)

| Bit Positions | 31:16 | 15:0 |
|---|---|---|
| Field Name | unused | Abort timer value |

The abort timer reload register is used exclusively by system microcode to establish the abort time interval. The abort time interval is the time allowed for the system to complete the last instruction of the current virtual machine activation time slice and acknowledge the switch interrupt signal.

The abort timer reload register can be initialized by system microcode during reset initialized data block (IDB) processing using a specified time-out value. The abort timer is loaded with the contents of the abort timer reload register when the switch interrupt alarm is generated. The abort timer reload value can be specified in units of CPU clock ticks.

Abort Timer Reload Register (ABO_RLR)

| Bit Positions | 31:16 | 15:0 |
|---|---|---|
| Field Name | unused | Abort timer reload value |

Note: Accesses to the abort timer reload register are performed by microcode in trusted mode. Memory protection logic, if implemented, should only allow access to this register when trusted mode is active (for example when the T/U signal is asserted so as to indicate trusted mode operation).

The prescalar reload register is used exclusively by the system microcode to establish the clocking rate of the switch interrupt timer and the virtual machine specific timer/counters. The prescalar is a continuous count-down timer that is driven by the CPU clock and generates a “clock” pulse for other timers upon reaching the zero count. Thereupon, the prescalar is automatically reloaded with the prescalar reload value to continue with the next count-down interval.

The prescalar reload register is initialized by system microcode during reset IDB processing using a specified clock interval (specified, for example, via a builder configuration tool). The prescalar reload value is specified in units of CPU clock ticks.

+UZ, 8/25 Prescalar Reload Register (PSCL_RLR)

| Bit Positions | 31:16 | 15:0 |
|---|---|---|
| Field Name | unused | Prescalar reload value |

Note: Accesses to the prescalar reload register are performed by microcode in trusted mode. Memory protection logic, if implemented, should only allow access to this register when trusted mode is active (for example, when the T/U signal is asserted so as to indicate trusted mode operation).

The VM switch interrupt alarm register is used exclusively by system microcode to establish the execution time slice for the activated virtual machine. The VM switch interrupt timer can be a continuous count-up timer driven by the prescalar clock and generates the VM switch interrupt when the counter matches the VM switch interrupt alarm value. Thereupon, the VM switch interrupt timer is automatically reset to zero and continues counting.

The VM switch interrupt alarm register is loaded by system microcode during the activation of a virtual machine. The virtual machine execution time interval (VM switch interrupt alarm value) can be set up using a suitable configuration tool. The VM switch interrupt alarm value is specified in units of prescalar “ticks”.

VM Switch Interrupt Alarm Register (VMSI_ALARM)

| Bit Positions | 31:16 | 15:0 |
|---|---|---|
| Field Name | unused | VM switch interrupt alarm value |

Note: Accesses to the VM switch interrupt alarm register are performed by microcode in trusted mode. Memory protection logic, if implemented, should only allow access to this register when trusted mode is active (for example, when the T/U is asserted so as to indicate trusted mode operation).

The timer mode register is used exclusively by system microcode to set up the MVM timers. The timer mode register is initialized during reset IDB processing depending on the configuration specified.

Timer Mode Register (TMODE)

| Bit Positions | 31:3 | 2 | 1 | 0 |
|---|---|---|---|---|
| Field Name | unused | VMSI enable | Abort enable | Prescalar enable |
| (VMSI enable: 0 = Disable switch interrupt timer, 1 = Enable switch interrupt timer. Abort enable: 0 = Disable abort timer, 1 = Enable abort timer. Prescalar enable: 0 = Disable prescalar, 1 = Enable prescalar.) Note: Accesses to the timer mode register are performed by microcode in trusted mode. Memory protection logic, if implemented, should only allow access to this register when trusted mode is active (for example when the T/U signal is asserted so as to indicate | | | | |
| #trusted mode operation). | | | | |

The read-only VM switch interrupt timer register is used exclusively by system microcode to provide deterministic virtual machine scheduling. The VM switch interrupt timer is a continuous count-up timer that is driven by the prescalar clock and generates the VM switch interrupt signal when the counter matches the VM switch interrupt alarm value. Upon reaching the VM switch interrupt alarm value, the VM switch interrupt timer is automatically reset to zero and continues counting. The VM switch interrupt timer value is read in units of prescalar “ticks”.

The VM switch interrupt signal is handled by system microcode to perform a context switch to the next virtual machine. The VM switch interrupt timer also triggers a watch dog timer (abort timer) to ensure that the interrupt is acknowledged.

VM Switch Interrupt Timer Register (VMSI)

| | | |
|---|---|---|
| Bit Positions | 31:16 | 15:0 |
| Field Name | unused | VMSI timer value |

Note: Accesses to the VM switch interrupt timer register are performed by microcode in trusted mode. Memory protection logic, if implemented, should only allow access to this register when trusted mode is active (for example when the T/U signal is asserted so as to indicate trusted mode operation).

The piano roll timer 0 reload register specifies the time interval when the piano roll is updated (periodic thread activation) for the VM0 context. The piano roll 0 timer is a continuous count-down timer driven by the prescalar clock and generates the PTO interrupt upon reaching the zero count. Thereupon, the piano roll timer 0 is automatically reloaded with the piano roll timer 0 reload value to continue with the next count-down interval.

The PTO interrupt is handled by system microcode during VM0 execution to update the piano roll index and activate any readied periodic thread. The piano roll timer 0 reload register is setup by the system runtime during the initialization of VM0.

The piano roll timer 0 reload value is specified in units of prescalar “ticks”.

Piano Roll Timer 0 Reload Register (PRT_RL0)

| | | |
|---|---|---|
| Bit Positions | 31:16 | 15:0 |
| Field Name | unused | Piano roll timer 0 reload value |

The clock timer 0 reload register specifies the time interval when the clock timer is updated (thread sleep queue) for the VM0 context. The clock timer is a continuous count-down timer that is driven by the prescalar clock and generates the TCO interrupt upon reaching the zero count. Thereupon, the clock timer 0 is automatically reloaded with the clock timer 0 reload value to continue with the next count-down interval.

The TCO interrupt is handled by system microcode during VM0 execution to update the thread sleep queue and activate any readied threads. The clock timer 0 reload register is setup by the system runtime during the initialization of VM0. The clock timer 0 reload value is specified in units of prescalar “ticks”.

Clock Timer 0 Reload Register (CT_RL0)

| | | |
|---|---|---|
| Bit Positions | 31:16 | 15:0 |
| Field Names | unused | Clock timer 0 reload value |

The VM0 timer enable register is used to set up the VM0 specific timers. The VM0 timer enable register is initialized by the system runtime depending on the configuration specified.

VM0 Timer Enable Register (TMR_EN0)

| | | | |
|---|---|---|---|
| Bit Positions | 31:2 | 1 | 0 |
| Field Names | unused | Clock Timer 0 enable | Piano roll timer 0 enable |

(Clock timer 0 enable: 0 = Disable clock timer 0, 1 = Enable clock timer 0. Piano roll timer 0 enable: 0 = Disable piano roll timer 0, 1 = Enable piano roll timer 0.)

The piano roll timer 0 register is used to provide deterministic periodic thread scheduling for the VM0 context. The piano roll 0 timer is a continuous count-down timer driven by the prescalar clock and generates the PTO interrupt upon reaching the zero count. Thereupon, the piano roll timer 0 is automatically reloaded with the piano roll timer 0 reload value to continue with the next count-down interval. The piano roll timer 0 value is read in units of prescalar “ticks”.

The PTO interrupt is handled by system microcode during VM0 execution to update the piano roll index and activate any readied periodic thread.

Piano Roll Timer 0 Register (PRT0)

| | | |
|---|---|---|
| Bit Positions | 31:16 | 15:0 |
| Field Names | unused | Piano roll timer 0 value |

The clock timer 0 register can be used to provide a 1 millisecond clock “tick” for the VM0 context. The clock timer is a continuous count-down timer that is driven by the prescalar clock and generates the TCO interrupt upon reaching the zero count. Thereupon, the clock timer 0 is automatically reloaded with the clock timer 0 reload value to continue with the next count-down interval. The clock timer 0 value is read in units of prescalar “ticks”.

The TCO interrupt is handled by system microcode during VM0 execution to update the thread sleep queue and activate any readied threads.

Clock Timer 0 Register (CT0)

| | | |
|---|---|---|
| Bit Positions | 31:16 | 15:0 |
| Field Name | unused | Clock timer 0 value |

The piano roll timer 1 reload register specifies the time interval when the piano roll is updated (periodic thread activation) for the VM1 context. The piano roll 1 timer is a continuous count-down timer that is driven by the prescalar clock and generates the PTO interrupt upon reaching the zero count. Thereupon, the piano roll timer 1 is automatically reloaded with the piano roll timer 1 reload value to continue with the next count-down interval.

The PTO interrupt is handled by system microcode during VM1 execution to update the piano roll index and activate any readied periodic thread. The piano roll timer 1 reload register is set up by the system runtime during the initialization of VM1. The piano roll timer 1 reload value is specified in units of prescalar “ticks”.

Piano Roll Timer 1 Reload Register (PRT_RL1)

| | | |
|---|---|---|
| Bit Positions | 31:16 | 15:0 |
| Field Name | unused | Piano roll timer 1 reload value |

The clock timer 1 reload register specifies the time interval when the clock timer is updated (thread sleep queue) for the VM1 context. The clock timer is a continuous count-down timer driven by the prescalar clock and generates the TCO interrupt upon reaching the zero count. Thereupon, the clock timer 1 is automatically reloaded with the clock timer 0 reload value to continue with the next count-down interval.

The TCO interrupt is handled by system microcode during VM1 execution to update the thread sleep queue and activate any readied threads. The clock timer 1 reload register is set up by the system runtime during the initialization of VM1. The clock timer 1 reload value is specified in units of prescalar “ticks”.

Clock Timer 1 Reload Register (CT_RL1)

| | | |
|---|---|---|
| Bit Positions | 31:16 | 15:0 |
| Field Name | unused | Clock timer 1 reload value |

The VM1 timer enable register is used to set up the VM1 specific timers. The VM1 timer enable register is initialized by the system runtime depending on the specified configuration.

VM1 Timer Enable Register (TMR_EN1)

| | | | |
|---|---|---|---|
| Bit Positions | 31:2 | 1 | 0 |
| Field Name | unused | Clock timer 1 enable | Piano roll timer 1 enable |

(Clock timer 1 enable: 0 = Disable clock timer 1, 1 = Enable clock timer 1. Piano roll timer 1 enable: 0 = Disable piano roll timer 1, 1 = Enable piano roll timer 1.)

The piano roll timer 1 register is used to provide deterministic periodic thread scheduling for the VM1 context. The piano roll 1 timer is a continuous count-down timer that is driven by the prescalar clock and generates the PTO interrupt upon reaching the zero count. Thereupon, the piano roll timer 1 is automatically reloaded with the piano roll timer 1 reload value to continue with the next count-down interval.

The piano roll timer 1 value is read in units of prescalar “ticks”.

The PTO interrupt is handled by system microcode during VM1 execution to update the piano roll index and activate any readied periodic thread.

Piano Roll Timer 1 Register (PRT1)

| | | |
|---|---|---|
| Bit Positions | 31:16 | 15:0 |
| Field Name | unused | Piano roll timer 1 value |

The clock timer 1 register is used to provide the 1 millisecond clock “tick” for the VM1 context. The clock timer is a continuous count-down timer that is driven by the prescalar clock and generates the TCO interrupt upon reaching the zero count. Thereupon, the clock timer 1 is automatically reloaded with the clock timer 1 reload value to continue with the next count-down interval. The clock timer 1 value is read in units of prescalar “ticks”.

The TCO interrupt is handled by system microcode during VM1 execution to update the thread sleep queue and activate any readied threads.

Clock Timer 1 Register (CT1)

| | | |
|---|---|---|
| Bit Positions | 31:16 | 15:0 |
| Field Name | unused | Clock timer 1 value |

The system can support up to 26 failing-edge activated, asynchronous, maskable, prioritized interrupts. Some of these interrupts may be used by logic integrated with the CPU processor core and others devoted to integrate peripheral devices and I/O pins. The four highest priority interrupts are nonmaskable including an external NMI available to the application. The interrupt assignments are summarized in the Interrupt Assignments table presented below.

Servicing the interrupt controller is entirely controlled by the executive microcode. Upon recognition of an interrupt, the microcode will interrogate the interrupt controller for the highest priority interrupt. (Note interrupt #0 is the highest priority interrupt.) The highest priority interrupt is cleared and the interrupt is either serviced internally (via microcoded interrupt handler) or the assigned software interrupt handler is invoked. (Interrupt handlers can be assigned using the build/configuration tool.)

Interrupt Assignments

| Interrupt | Name | Description |
|---|---|---|
| 0 | Transfer Error | Nonmaskable interrupt generated by |
| | (XERR) | external memory protection logic when a |
| | | memory access is attempted outside of the |
| | | VM's enabled memory space. MVM |
| | | memory protection must be enabled to |
| | | allow this interrupt generation. This |
| | | interrupt is handled internally by |
| | | the executive microcode and is fatal |
| | | to the current VM context. |
| 1 | Power down | Nonmaskable interrupt generated by ex- |
| | warning (PDW) | ternal logic to signal power is going away. |
| | | The power down handler for each VM is |
| | | checked and invoked if present to prepare |
| | | for power interruption and halt the VM. |
| 2 | VM Switch | Nonmaskable interrupt generated by the |
| | Interrupt | internal JSI timer to signal the context |
| | (VMSI) | switch to the next JVM environment. This |
| | | interrupt is handled internally by the |
| | | executive microcode which performs the |
| | | context switch to the next VM. |
| 3 | External NMI | Nonmaskable interrupt generated by ex- |
| | (ENMI) | ternal logic for application specific events |
| 5 | Arithmetic | Maskable Interrupt (VM specific) gener- |
| | error (OVR) | ated internally when an arithmetic error |
| | | is detected during instruction execution. |
| | | Arithmetic errors include integer arith- |
| | | metic overflows (number can't be repre- |
| | | sented in the data type) and the detection |
| | | / generation of floating point NaNs and |
| | | infinities. (Note that Java only supports |
| | | divide by zero detection.) Arithmetic error |
| | | detection can be enabled for either VM0 |
| | | and/or VM1. |
| 7 | Timer/counter | Maskable interrupt (VM specific) gener- |
| | output (TCO) | ated internally when the internal timer/ |
| | | counter counts down to zero. The timer/ |
| | | counter alarm can be enabled for either |
| | | VM0 and/or VM1. This interrupt is hand- |
| | | led internally by the executive microcode |
| | | to update the VM specific sleep queue. |
| 8 | Piano roll timer | Maskable interrupt (VM specific) gener- |
| | output (PTO) | ated internally when the internal piano |
| | | roll timer counts down to zero. The |
| | | piano roll alarm can be enabled for |
| | | either VM0 and/or VM1. This interrupt |
| | | is handled internally by the executive |
| | | microcode to update the VM specific |
| | | piano roll for periodic thread |
| | | scheduling. |
| 25:10 | Peripheral | Maskable interrupts assigned according to |
| | Interrupts | the peripheral interrupt translation |
| | | registers. |

The system allows the user to declare the priority level of each internal interrupt source. The interrupt architecture assigns interrupt 0 as the highest priority interrupt. Interrupts 0 through 9 are reserved for use by the Multiple VM logic. The internal peripherals may be assigned a priority from 10 to 25 via the individual interrupt level translation registers. The builder can be used to specify the interrupt levels. This will cause the level translation registers to be initialized as part of the reset process.

The interrupt slip register is used to identify any interrupts that occurred more than once before they have been serviced. Bits set in the interrupt slip register indicate that multiple interrupts have occurred for the corresponding interrupt number. The interrupt slip register is useful for determining if system processing is overloaded such that interrupts are being missed.

Interrupt Slip Register (ISR)

| | | |
|---|---|---|
| Bit Positions | 31:26 | 25:0 |
| Field Name | unused | Interrupt bit field |

The pending interrupt register is used exclusively by the microcode to identify the highest priority pending interrupt and initiate the interrupt service routine. (Note: interrupt #0 is the highest priority interrupt.) The highest priority pending interrupt is cleared and the interrupt is either serviced internally (via a microcoded interrupt handler) or the assigned software interrupt handler is invoked. (Interrupt handlers can be assigned using the build/configuration tool.)

Pending Interrupt Register (PIR)

| | | |
|---|---|---|
| Bit Positions | 31:26 | 25:0 |
| Field Name | unused | Interrupt bit field |

Note: Accesses to the pending interrupt register are performed by microcode in trusted mode. Memory protection logic, if implemented, should only allow access to this register when trusted mode is active (for example, when T/U has been asserted so as to indicate trusted mode operation).

It is thought that the method and apparatus of the present invention will be understood from the description provided throughout this specification and the appended claims, and that it will be apparent that various changes may be made in the form, construct steps and arrangement of the parts and steps thereof, without departing from the spirit and scope of the invention or sacrificing material advantages. The forms herein described are merely representative embodiments thereof. For example, although some embodiments of the invention have been described in relation to JAVA virtual machines, the present inventions are capable of being used with other types of virtual machines or languages that have been, or will be, developed. The Common Language Infrastructure (CLI) of the Microsoft.NET system is an example of one such language. Further, it will be appreciated that a variety of different programming languages are available and appropriate for use with the various embodiments.

1. A method for managing interrupts in a multiple virtual machine environment, comprising the steps of:
running concurrently a plurality of independent virtual machines, each virtual machine having associated therewith a plurality of anticipated interrupt signal types;
receiving a plurality of interrupt signals;
determining which interrupt signal of the plurality of received interrupt signals has the highest priority; and
servicing the interrupt signal determined to have the highest priority.

2. The method of claim 1, wherein said running step comprises running at least two Java virtual machines.

3. The method of claim 3, further comprising the step of activating a specific independent virtual machine of said plurality of independent virtual machines.

4. The method of claim 3, wherein said activating step comprises the step of using a timer to define an activation period of an activated virtual machine.

5. The method of claim 3, further comprising the step of assigning a memory region to at least one independent virtual machine of the plurality of independent virtual machines.

6. The method of claim 5, further comprising the step of protecting a virtual machine's memory region from accesses by a different virtual machine.

7. The method of claim 6, wherein said protecting step comprises the steps of:
screening a memory access; and
generating an abort interrupt signal to abort an access to a memory region of a nonactivated virtual machine.

8. The method of claim 5, further comprising the step of outputting the identity of the activated virtual machine to a memory management component.

9. The method of claim 8, further comprising the step of identifying, by the memory management component, the memory region assigned to the activated virtual machine.

10. The method of claim 9, further comprising the step of monitoring address lines to abort attempted memory accesses to a protected memory region.

11. The method of claim 10, further comprising the step of aborting an attempted access to a protected memory region by generating an error signal.

12. The method of claim 10, further comprising the step of aborting an attempted access to a protected memory region by generating a prioritized nonmaskable interrupt signal.

13. The method of claim 10, further comprising the step of aborting an attempted access to a protected memory region by generating a highest priority prioritized nonmaskable interrupt signal.

14. The method of claim 3, wherein said receiving step comprises receiving a maskable interrupt signal.

15. The method of claim 14, further comprising the step of latching a received maskable interrupt signal.

16. The method of claim 14, further comprising the step of latching a received maskable interrupt signal into a virtual interrupt latch component even though the independent virtual machine with which it is associated is not the activated independent virtual machine at the time the received maskable interrupt signal is received.

17. The method of claim 16, further comprising the step of transferring the maskable interrupt signal, upon activation of its associated virtual machine, from the virtual interrupt latch component to a global interrupt mask register.

18. The method of claim 17, further comprising the step of transferring the maskable interrupt signal, upon activation of its associated virtual machine, from the virtual interrupt latch component to a local mask register.

19. The method of claim 18, further comprising the step of sending the maskable interrupt signal, upon activation of its associated virtual machine, to a priority encoder after said steps of transferring and communicating.

20. The method of claim 16, further comprising the steps of:
holding the received maskable interrupt signal in the virtual interrupt latch component until the independent virtual machine with which it is associated has been activated; and
servicing the received maskable interrupt signal during the time period that its associated independent virtual machine has been activated.

21. The method of claim 14, further comprising the steps of:
discerning whether the independent virtual machine associated with the received maskable interrupt signal is the activated independent virtual machine; and
ignoring the received maskable interrupt signal if it is discerned that the independent virtual machine with which the received maskable interrupt signal is associated is not the currently activated independent virtual machine.

22. The method of claim 1, wherein said receiving step comprises receiving a nonmaskable interrupt signal.

23. The method of claim 1, wherein said receiving step comprises receiving a nonmaskable interrupt signal indicating a power supply interruption.

24. The method of claim 3, wherein said receiving step comprises receiving a nonmaskable interrupt signal indicating activation of a different independent virtual machine.

25. The method of claim 1, wherein said receiving step comprises receiving a nonmaskable interrupt signal indicating an application specific event.

26. The method of claim 1, wherein said receiving step comprises receiving a nonmaskable interrupt signal indicating a prohibited memory access attempt.

27. The method of claim 3, further comprising the step of reserving the highest priority for interrupt signals indicating a prohibited memory access attempt;
and wherein said receiving step comprises receiving a nonmaskable interrupt signal indicating a prohibited memory access attempt.

28. The method of claim 27, further comprising the step of suspending execution of the activated independent virtual machine upon receipt of a nonmaskable interrupt signal indicating a prohibited memory access attempt.

29. An interrupt management system for an apparatus capable of running multiple concurrent virtual machines, comprising:
a timer component comprising a plurality of virtual machine timers, said timer component further comprising an active virtual machine switch signal output;
a multiple virtual machine control component, comprising an active virtual machine identification signal output;
a processor component, coupled with said timer component;
an interrupt controller component coupled with said processor component and with said timer component, said interrupt controller component comprising an active virtual machine identification signal input coupled with said active virtual machine identification signal output, said interrupt controller component also comprising an interrupt signal input; and
a memory component storing interrupt handler code.

30. The interrupt management system of claim 29, wherein said interrupt controller component further comprises a plurality of virtual interrupt latch components.

31. The interrupt management system of claim 30, further comprising a plurality of global interrupt mask registers.

32. The interrupt management system of claim 30, further comprising a plurality of global interrupt mask registers, and wherein each global interrupt mask register is coupled with one of the virtual interrupt latch components.

33. The interrupt management system of claim 32, further comprising a local mask register coupled with said plurality of global interrupt mask registers.

34. The interrupt management system of claim 33, further comprising a priority encoder coupled with said local mask register.

35. An interrupt controller for a multiple virtual machine environment, comprising:<
an interrupt signal input;
a plurality of virtual interrupt latch components coupled with said interrupt signal input; and
a plurality of global interrupt mask registers;
wherein each global interrupt mask register of said plurality of global interrupt mask registers is coupled with one of the virtual interrupt latch components.

36. The interrupt controller of claim 35, further comprising a local mask register coupled with said plurality of global interrupt mask registers.

37. The interrupt controller of claim 36, further comprising a priority encoder coupled with said local mask register.

38. A processor-based interrupt signal management system for a multiple virtual machine environment, comprising:
an integrated circuit chip, comprising;
a processor component;
a multiple virtual machine management component coupled with said processor component, said multiple virtual machine management component comprising a plurality of virtual machine activation timer components;
a memory component coupled with said processor component, said memory component comprising interrupt handler code;
a memory access error input;
an active virtual machine identification output; and
a memory access location output; and
an external memory protection component, not located on said integrated circuit chip, comprising an active virtual machine identification input and a memory access location input, said active virtual machine identification input coupled with said active virtual machine identification output and said memory access location input coupled with said memory access location output of said integrated circuit chip, said external memory protection component comprising a memory access error output, said memory access error output coupled with said memory access error input;
wherein said external memory protection component indicates a memory access error via said memory access error output when said memory access location input indicates memory location not associated with a virtual machine identified by said active virtual machine identification output.
